(19) United States
(12) Patent Application Publication
(10) Pub. No.: US 2024/0203731 A1
(43) Pub. Date: Jun. 20, 2024

(54) METHOD OF MANUFACTURING AN ELECTRONIC DEVICE

(71) Applicant: Commissariat à I'Énergie Atomique et aux Énergies Alternatives, Paris (FR)

(72) Inventors: Rémy Gassilloud, Grenoble Cedex 9 (FR); Julien Patouillard, Grenoble (FR); Bérangére Hyot, Grenoble Cedex 9 (FR); Amélie Dussaigne, Grenoble Cedex 9 (FR); Stéphane Cadot, Grenoble Cedex 9 (FR); Matthew Charles, Grenoble Cedex 9 (FR); François Martin, Grenoble Cedex 9 (FR); Nicolas Gauthier, Grenoble Cedex 9 (FR); Christine Raynaud, Grenoble Cedex 9 (FR)

(73) Assignee: Commissariat à I'Énergie Atomique et aux Énergies Alternatives, Paris (FR)

(21) Appl. No.: 18/537,875

(22) Filed: Dec. 13, 2023

(30) Foreign Application Priority Data
Dec. 19, 2022 (FR) 2213810

(51) Int. Cl. H01L 21/02

(52) U.S. Cl. CPC H01L 21/0254; H01L 21/02529; H01L 21/02568; H01L 21/02581; H01L 21/02631; H01L 21/02664

(57) ABSTRACT

A method including the following successive steps: a) forming, on a surface of a support substrate, a first layer made of a material selected from among a lamellar dichalcogenide or a lamellar chalcogenide including a stack of sheets; b) forming, by physical vapor deposition on the side of said surface of the support substrate, a second layer made of a first III-N semiconductor material coating the first layer; and c) carrying out a thermo-chemical treatment of the first layer resulting, in the first layer, in a conversion of van der Waals bonds between the sheets of the first layer into covalent bonds.

This application claims priority to French application number 2213810, filed Dec. 19, 2022, the contents of which is incorporated herein by reference in its entirety.

### TECHNICAL BACKGROUND

The present disclosure generally concerns electronic devices. The present disclosure more particularly aims at methods of manufacturing electronic devices based on semiconductor materials.

### PRIOR ART

Electronic devices comprising a region made of a semiconductor material, for example, a III-N material, that is, a nitride of an element from the thirteenth column of the periodic table, have been provided. In particular, aluminum nitride and gallium nitride are direct bandgap III-N semiconductor materials used in various applications such as power electronics, radio frequency communications, lighting, etc.

However, the implementation of current methods of manufacturing electronic devices based on semiconductor materials turns out being expensive and complex. These methods for example implement buffer layers allowing a lattice parameter matching between a substrate, for example, made of silicon, and the layer(s) based on semiconductor material, buffer layers being subject to rupture problems during cooling steps subsequent to the forming of the layer(s) based on semiconductor material.

### SUMMARY OF THE INVENTION

There is a need to improve existing methods of manufacturing electronic devices based on semiconductor materials.

For this purpose, an embodiment provides a method comprising the following successive steps:
a) forming, on a surface of a support substrate, a first layer made of a material selected from among a lamellar dichalcogenide or a lamellar chalcogenide comprising a stack of sheets;
b) forming, by physical vapor deposition on the side of said surface of the support substrate, a second layer made of a first III-N material coating the first layer; and
c) carrying out a thermo-chemical treatment of the first layer resulting, in the first layer, in a conversion of van der Waals bonds between the sheets of the first layer into covalent bonds.

According to an embodiment, at step c), the thermo-chemical treatment is an anneal carried out under a reducing atmosphere.

According to an embodiment, at step c), the thermo-chemical treatment is performed under a nitrogenous atmosphere, preferably under an ammonia or nitrogen atmosphere.

According to an embodiment, at step c), the thermo-chemical treatment is carried out under a hydrogen atmosphere.

According to an embodiment, at step c), the thermo-chemical treatment further results in a conversion of van der Waals bonds into covalent bonds between the first layer and the support substrate.

According to an embodiment, the first semiconductor material is aluminum nitride.

According to an embodiment, the first III-N semiconductor material is doped, preferably, with scandium atoms.

According to an embodiment, the method further comprises, after step c), a step d) of forming of a third layer made of a second semiconductor material coating the second layer, the third layer having a thickness greater than that of the second layer.

According to an embodiment, the second semiconductor material is a III-V, preferably III-N, semiconductor material.

According to an embodiment, the second semiconductor material is silicon carbide.

According to an embodiment, the second semiconductor material is identical to the first semiconductor material.

According to an embodiment, the third layer is doped.

According to an embodiment, the method further comprises, after step d), a step e) of forming of at least a fourth layer coating the third layer.

According to an embodiment, at step c), the thermo-chemical treatment is accompanied by a plasma treatment.

According to an embodiment, the first layer is made of a transition metal dichalcogenide, preferably of molybdenum disulfide or of tungsten disulfide.

According to an embodiment, at step c), the thermo-chemical treatment is carried out at a temperature in the range from 300 to 1,500° ° C., preferably in the range from 800 to 1,000° C.

According to an embodiment, the second layer has a thickness in the range from 0.15 to 50 nm, preferably in the range from 1 to 6 nm.

### BRIEF DESCRIPTION OF THE DRAWINGS

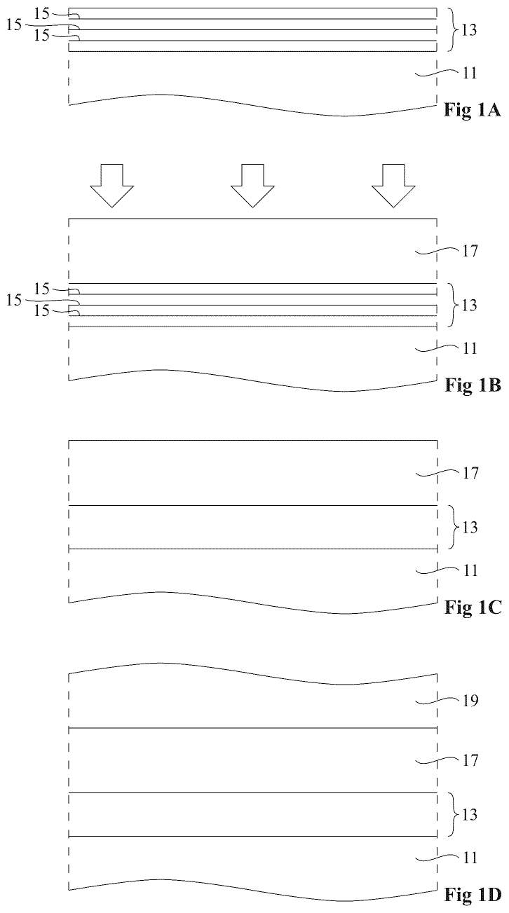

The foregoing and other features and advantages will be discussed in detail in the following non-limiting description of specific embodiments in connection with the accompanying drawings, among which FIG. 1A, FIG. 1B, FIG. 1C, and FIG. 1D are simplified and partial cross-section views illustrating successive steps of an example of a method of manufacturing an electronic device based on a semiconductor material according to an embodiment.

### DESCRIPTION OF THE EMBODIMENTS

Like features have been designated by like references in the various figures. In particular, the structural and/or functional features that are common among the various embodiments may have the same references and may dispose identical structural, dimensional and material properties.

For the sake of clarity, only the steps and elements that are useful for an understanding of the embodiments described herein have been illustrated and described in detail. In particular, the electronic device manufacturing steps subsequent to the forming of a layer made of a semiconductor material as well as the various applications likely to benefit from such a device have not been detailed, the described embodiments being compatible with usual steps of manufacturing of an electronic device based on a layer made of a semiconductor material and with usual applications using such devices.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, when reference is made to terms qualifying absolute positions, such as terms “front”, “back”, “top”, “bottom”, “left”, “right”, etc., or relative positions, such as terms “above”, “under”, “upper”, “lower”, etc., or to terms qualifying directions, such as terms “horizontal”, “vertical”, etc., it is referred, unless specified otherwise, to the orientation of the drawings.

Unless specified otherwise, the expressions “about”, “approximately”, “substantially”, and “in the order of” signify plus or minus 11%, preferably of plus or minus 5%.

FIG. 1A, FIG. 1B, FIG. 1C, and FIG. 1D are simplified and partial cross-section views illustrating successive steps of an example of a method of manufacturing an electronic device based on a semiconductor material according to an embodiment.

As an example, the steps described hereafter in relation with FIGS. 1A to 1D form part of a method of forming a radio frequency filter of SAW (“Surface Acoustic Wave”) or BAW (“Bulk Acoustic Wave”) type, a HEMT (“High Electron Mobility Transistor”) power transistor, a device of laser or LED (“Light-Emitting Diode”) type, a sensor of beam oscillator type, a thermal sensor, etc. or more generally, any type of method of manufacturing an electronic device comprising at least one region made of an inorganic semiconductor material, for example, a III-N semiconductor material. As a variant, the following steps may apply to the forming of a coating layer, for example, a tribological layer, for example, based on aluminum nitride.

FIG. 1A more particularly illustrates a structure obtained at the end of a step of forming, on a surface of a support substrate 11 (the upper surface of support substrate 11, in the orientation of FIG. 1A), of a layer 13 made of a transition metal dichalcogenide (TMD).

Support substrate 11 may be made of any material, for example, silicon, sapphire, silicon carbide, silicon nitride, alumina, aluminum nitride, borosilicate glass, etc. Support substrate 11 is for example a single-crystal silicon wafer having a diameter in the range from 50 to 300 mm, for example equal to approximately 200 mm, with its upper surface having a (100) orientation. As a variant, support substrate 11 is of SOI (“Silicon On Insulator”) type and comprises a silicon layer coated with a silicon dioxide layer, itself coated with another silicon layer. Further, support substrate 11 may comprise active elements not shown in FIG. 1A, such as transistors, or may have a reflective structure, for example, of Bragg mirror type.

According to the targeted application, support substrate 11 may be non-intentionally doped or may as a variant have a doping level providing it, for example, with specific thermal and/or electric properties.

Further, although FIG. 1A illustrates an example where support substrate 11 has substantially planar lower and upper surfaces parallel to each other, this example is not limiting, and the lower and upper surfaces of substrate 11 may, as a variant, each have any shape. As an example, the upper surface of support substrate 11 may be non planar, and may for example have a relief adapted to the subsequent forming of vertical light-emitting diodes, for example, a “stepped” shape comprising asperities and protruding portions.

In the example illustrated in FIG. 1A, layer 13 of transition metal dichalcogenide has a lamellar or stratified structure comprising, from the upper surface of support substrate 11, a vertical stack of a plurality of sheets 15 substantially parallel to the upper surface of support substrate 11 and bonded together by van der Waals bonds. Each of sheets 15, also called two-dimensional layers, 2D layers, or monolayers, for example has a hexagonal arrangement of the atoms of the transition metal to which are bonded, by covalent bonds, the chalcogen atoms. In the orientation of FIG. 1, the lowest sheet 15 in the stack, that is, the sheet 15 closest to support substrate 11, is for example further bonded to the upper surface of support substrate 11 by van der Waals bonds and/or by covalent bonds. Although four sheets 15 have been symbolized in FIG. 1A, this example is not limiting and layer 13 may comprise any number of sheets 15, for example, between one and fifty.

The transition metal dichalcogenide has a chemical formula of type MX2, where M represents the transition metal and X the chalcogen element. Transition metal M is for example selected from among molybdenum, tungsten, vanadium, niobium, tantalum, titanium, zirconium, hafnium, and alloys of these metals. Chalcogen element X is for example selected from among sulfur, selenium, and tellurium. As an example, the transition metal dichalcogenide is a transition metal disulfide having a chemical formula of type MS₂, for example, molybdenum disulfide (MoS₂), tungsten disulfide (WS₂), or vanadium disulfide (VS₂).

Layer 13 of transition metal dichalcogenide is for example formed by deposition, for example, by ALD (“Atomic Layer Deposition”), for example according to the method described in French patent No. 3016889, or by CVD (“Chemical Vapor Deposition”) on the upper surface side of support substrate 11. As a variant, layer 13 of transition metal dichalcogenide may first be formed on a surface of a transfer substrate, or handle, and then transferred onto the upper surface of support substrate 11.

As an example, an amorphous molybdenum disulfide layer coating the upper surface of support substrate 11 is first formed by ALD at a temperature equal to approximately 90° ° C. This amorphous layer is for example then sulfurized, for example by exposure to ethanedithiol (EDT) at a temperature equal to approximately 450° C., to modify, or correct, its stoichiometry. Finally, a crystallization anneal under nitrogen, for example, at a flow rate in the order of 2 L·min⁻¹, under the atmospheric pressure, at a temperature equal to approximately 900° C. and for a duration in the order of 30 s, is implemented to form the sheets 15 of layer 13. In the case where support substrate 11 is made of silicon, substrate 11 may, prior to the forming of layer 13 of transition metal dichalcogenide, be oxidized from its upper surface down to a depth for example in the order of 500 nm.

FIG. 1B more particularly illustrates a structure obtained at the end of a subsequent step of forming of a layer 17 made of a III-N semiconductor material on the structure obtained at the end of the steps previously described in relation with FIG. 1A.

In the shown example, layer 17 of III-N semiconductor material covers the surface of layer 13 of transition metal dichalcogenide opposite to support substrate 11 (the upper surface of layer 13, in the orientation of FIG. 1B). As an example, layer 17 has a thickness in the range from 0.15 to 50 nm, preferably in the range from 1 to 6 nm, for example, equal to approximately 5 nm. The material of layer 17 is a nitride of at least one element from the thirteenth group of the periodic table of elements, also called group IIIB in the IUPAC system and group IIIA in the CAS system, for example, aluminum, gallium, or indium. The material of layer 17 is for example a III-N binary compound, for example, aluminum nitride or gallium nitride, or a ternary compound, for example, indium-gallium nitride, or also an alloy based on aluminum nitride, for example a compound having a chemical formula of the type Al_{(1-α)}X_{α}N, where X is any element from the periodic table, for example, scandium, yttrium, lanthanum, magnesium, titanium, vanadium, chromium, or molybdenum, and where α varies between 0 and 0.5, preferably between 0.03 and 0.2. As a variant, the material of layer 17 is a quaternary compound, for example, indium-aluminum-gallium nitride (InGaN:Al).

Further, in the case where layer 17 is made of a ternary or quaternary III-N semiconductor material, layer 17 may exhibit, from the upper surface of lamellar layer 13, a concentration gradient for at least one of the elements of the compound, for example one of the elements from the thirteenth group. As an example, layer 17 may be made of AlGaN and have a gallium content increasing away from layer 13.

In the case where layer 17 is made of aluminum nitride, the material of layer 17 is for example crystallized in a wurtzite structure with a hexagonal mesh, the hexagons having a (002) orientation along a direction orthogonal to the upper surface of support substrate 11.

Layer 17 of semiconductor material III-N is for example formed by physical vapor deposition (PVD), for example, according to the method described in French patent No. 3105591. As an example, layer 17 is formed by cathode sputtering at a temperature in the order of 350° C. An argon and nitrogen plasma is for example formed and then accelerated, for example by means of a DC current source, towards an aluminum target. Under the action of the plasma, aluminum atoms are torn off from the target. These atoms react with the nitrogen of the plasma and form an aluminum nitride depositing on layer 13 of transition metal dichalcogenide. Support substrate 11 is for example submitted to no bias voltage during the forming of layer 17 to avoid damaging layer 13. As a variant, layer 17 of semiconductor material may be formed by PLD (“Pulsed Laser Deposition”).

FIG. 1B further illustrates a subsequent step of thermal treatment, or anneal, of the structure comprising support substrate 11 and layers 13 and 17. The thermal treatment step, symbolized by vertical arrows in FIG. 1B, aims at increasing the inner cohesion of layer 13 as well as the adhesion of layer 13 to support substrate 11, which substrate 11 is not intended to be removed during subsequent steps of the method of manufacturing the device. During the thermal treatment, the van der Waals bonds between adjacent sheets of layer 13 are transformed into covalent bonds, having bonding energies greater than those of the van der Waals bonds initially coupling the adjacent sheets 15 together. Similarly, the van der Waals bonds between the bottom sheet 15 of layer 13 and substrate 11 may be transformed into covalent bonds during this step.

The thermal treatment is for example performed under a nitrogenous atmosphere in a reducing atmosphere, for example by thermal nitriding in the presence of a nitrogenous gas such as ammonia (NH₃), nitrogen, or a nitrogen oxide of NOx type, or in the presence of a nitrogen propellant, for example, hydrazine (N₂H₄), or also in the presence of a gas or of a gas mixture adapted to nitriding layer 13 through layer 15, for example, a mixture of nitrogen and of hydrogen. The nitriding enables to at least partially transform the transition metal dichalcogenides of layer 13 into nitride or into oxynitride of said transition metal, for example, to at least partially transform the molybdenum disulfide into molybdenum nitride (MoN). According to the applied thermal budget, the conversion of the van der Waals bonds into covalent bonds may result in the forming of metallic transition metal alone or of at least partially nitrided transition metal, for example of metallic molybdenum or of partially nitrided molybdenum in the case where layer 13 is made of MoS₂.

As a variant, the thermal treatment may be performed under a hydrogen atmosphere. In this case, layer 13 is for example at least partially transformed into metal balls based on the transition metal of layer 13, for example, into metal molybdenum balls.

The thermal treatment is for example carried out in a furnace at a temperature in the range from 300 to 1,300° C., preferably from 800 to 1,000° C. The pressure inside of the furnace is for example lower than or equal to 1 bar, for example in the order of 400 mbar. As a variant, the pressure inside of the furnace may be hyperbaric. A plasma assistance may further be provided, for example, a plasma of type CCP (“Capacitively Coupled Plasma”) 1,000 W 2.67 mbar N₂/H₂ at 500° C. More generally, the step illustrated in FIG. 1B corresponds to the implementation of a thermo-chemical treatment.

As an example, the anneal is performed:
at a temperature equal to approximately 1,000° C., for a duration equal to approximately 1 h, at an ammonia pressure in the order of 150 mbar and under a flow of approximately 3 L·min⁻¹;
at a temperature equal to approximately 1,000° C., for a duration equal to approximately 10 min, at an ammonia pressure in the order of 400 mbar and under a flow of approximately 3 L·min⁻¹;
at a temperature equal to approximately 800° C., for a duration equal to approximately 10 min, at an ammonia pressure in the order of 400 mbar and under a flow of approximately 3 L·min⁻¹; or
at a temperature equal to approximately 1,000° ° C., for a duration equal to approximately 1 h, at an ammonia pressure in the order of 50 mbar and under a flow of approximately 0.05 L·min⁻¹.

FIG. 1C more particularly illustrates a structure obtained at the end of the thermo-chemical treatment step previously described in relation with FIG. 1B.

As illustrated in FIG. 1C, the thermo-chemical treatment for example result in a crystal reorganization of layer 13, initially appearing in the form of a stack of two-dimensional sheets 15, into a three-dimensional structure. This advantageously enables to mechanically hold layer 17 of III-N semiconductor material on support substrate 11, layer 17 being attached to substrate 11 via layer 13.

FIG. 1D more particularly illustrates a structure obtained at the end of subsequent and optional step of regrowth on layer 17 of III-N semiconductor material.

In the shown example, a layer 19 coats the surface of layer 17 of III-N semiconductor material opposite to support substrate 11 (the upper surface of layer 17, in the orientation of FIG. 1D). As an example, layer 19 is made of a III-V semiconductor material, for example, a material selected from the list of materials mentioned hereabove for layer 17, for example, aluminum nitride. Layer 19 is for example made of the same material as layer 17 and may further comprise a transition element, for example, scandium, or another dopant compound, for example, magnesium-zirconium (MgZr), enabling for example to modify the mechanical and acoustic properties of layer 19. As an example, the material of layer 19 is a binary III-V compound, for example, indium phosphide, gallium arsenide or indium arsenide, a ternary III-V compound or a quaternary III-V compound, for example, selected from among those previously mentioned for layer 17.

Similarly to layer 17, layer 19 may exhibit a concentration gradient for at least one of the elements of the compound.

As a variant, for example for applications in the field of power electronics, layer 19 may be made of silicon carbide.

Layer 19 for example has a thickness greater than that of layer 17. As an example, layer 19 has a thickness greater than 100 nm.

Layer 19 is for example formed identically or similarly to layer 17, for example, by PVD, for example according to the method described in French patent No. 3105591. Support substrate 11 is for example submitted to a bias voltage during the forming of layer 19. As a variant, the III-N semiconductor material of layer 19 may be deposited by MOCVD (“Metalorganic Chemical Vapor Deposition”), for example, at a temperature in the order of 1,100° C. As a variant, layer 19 is formed by PLD or by inorganic CVD, for example, chlorine CVD.

As an example, the step of forming of layer 19 on layer 17 is implemented within the shortest possible delay after having carried out the thermal treatment step. This advantageously enables to avoid or to limit the oxidation of the material of layer 17, and thus to obtain a layer 19 of optimal crystal quality. As a variant, a step of deoxidizing treatment and/or of keeping of layer 17 under a non-oxidizing atmosphere may be provided.

Although this has not been shown in FIG. 1D, one or a plurality of other layers, for example, based on III-V semiconductor materials or on silicon carbide, may be subsequently formed on layer 19, for example to form one or a plurality of quantum wells, a two-dimensional electron gas, etc. As an example, in the case where layer 17 is made of aluminum nitride, layer 19 is for example made of aluminum nitride and may be coated with another layer of aluminum-gallium nitride, itself coated with still another gallium nitride layer.

Subsequent steps of the electronic device manufacturing method may then be implemented from the structure of FIG. 1D, support substrate 11 being intended to be kept at the end of these steps. As an example, steps of photolithography and then etching and/or deposition may be implemented from the structure illustrated in FIG. 1D.

An advantage of the method described hereabove in relation with FIGS. 1A to 1D lies in the fact that the structure of layer 13 of transition metal dichalcogenide enables to absorb the strain induced by a lattice parameter mismatch between the material of layer 15 and that of layer 13. The fact of providing layer 13 further enables to form layer 17, and possibly layer 19, on any type of support substrate 11. This particularly has the advantage of enabling to do away with the use of a single-crystal silicon substrate. This results in a decrease in the cost of the electronic device obtained according to this method.

Another advantage of the method described hereabove in relation with FIGS. 1A to 1D lies in the fact that the lamellar structure of dichalcogenide layer 13 enables to improve the crystal texturing of layers 17 and 19, particularly the preferred orientation of the hexagonal mesh of the III-Ns perpendicular to the growth surface. The fact of providing layer 13 enables to form textured layers 17 and 19, on any type of support substrate 11. This particularly has the advantage of enabling to do away with the use of an epitaxy relation between a monocrystalline substrate and a III-N. This results in a decrease in the cost of the electronic device obtained according to this method.

Another advantage of the method described hereabove in relation with FIGS. 1A to 1D lies in the fact that the thermal treatment step enables to avoid the occurrence of a delamination phenomenon between layer 13 and support substrate 11, or between the sheets 15 of layer 13, during the forming of layer 19. This results in an improvement of the mechanical resistance of the device obtained according to this method.

Although an embodiment where layer 13 is made of a transition metal dichalcogenide has been described hereabove, this example is not limiting and layer 13 may, as a variant, be made of any type of lamellar chalcogenide or dichalcogenide material. As an example, layer 13 may be made of a lamellar chalcogenide or monochalcogenide, for example, of a transition metal chalcogenide having a chemical formula of type MX (M representing the transition metal and X the chalcogen element) or of a post-transition metal chalcogenide, for example, zinc sulfide, tin sulfide, or tin disulfide.

Various embodiments and variants have been described. Those skilled in the art will understand that certain features of these various embodiments and variants may be combined, and other variants will occur to those skilled in the art.

Finally, the practical implementation of the described embodiments and variants is within the abilities of those skilled in the art based on the functional indications given hereabove. Further, the described embodiments are not limited to the examples of materials and of dimensions mentioned hereabove.

What is claimed is:

1. Method comprising the following successive steps:
a) forming, on a surface of a support substrate, a first layer made of a material selected from among a lamellar dichalcogenide or a lamellar chalcogenide comprising a stack of sheets;
b) forming, by physical vapor deposition on the side of said surface of the support substrate, a second layer made of a first III-N semiconductor material coating the first layer; and
c) carrying out a thermo-chemical treatment of the first layer resulting, in the first layer, in a conversion of van der Waals bonds between the sheets of the first layer into covalent bonds.

2. Method according to claim 1, wherein, at step c), the thermo-chemical treatment is an anneal carried out under a reducing atmosphere.

3. Method according to claim 1, wherein, at step c), the thermo-chemical treatment is carried out under a nitrogenous atmosphere, preferably under an ammonia or nitrogen atmosphere.

4. Method according to claim 1, wherein, at step c), the thermo-chemical treatment is carried out under a hydrogen atmosphere.

5. Method according to claim 1, wherein, at step c), the thermo-chemical treatment further results in a conversion of van der Waals bonds into covalent bonds between the first layer and the support substrate.

6. Method according to claim 1, wherein the first semiconductor material is aluminum nitride.

7. Method according to claim 1, wherein the first III-N semiconductor material is doped, preferably with scandium atoms.

8. Method according to claim 1, further comprising, after step c), a step d) of forming of a third layer made of a second semiconductor material coating the second layer, the third layer having a thickness greater than that of the second layer.

9. Method according to claim 8, wherein the second semiconductor material is a III-V, preferably III-N, semiconductor material.

10. Method according to claim 8, wherein the second semiconductor material is silicon carbide.

11. Method according to claim 8, wherein the second semiconductor material is identical to the first semiconductor material.

12. Method according to claim 8, wherein the third layer is doped.

13. Method according to claim 8, further comprising, after step d), a step e) of forming of at least one fourth layer coating the third layer.

14. Method according to claim 1, wherein, at step c), the thermo-chemical treatment is accompanied by a plasma treatment.

15. Method according to claim 1, wherein the first layer is made of a transition metal dichalcogenide, preferably of molybdenum disulfide or of tungsten disulfide.

16. Method according to claim 1, wherein, at step c), the thermo-chemical treatment is carried out at a temperature in the range from 300 to 1,500° C., preferably in the range from 800 to 1,000° C.

17. Method according to claim 1, wherein the second layer has a thickness in the range from 0.15 to 50 nm, preferably in the range from 1 to 6 nm.
